(19) United States
(12) Patent Application Publication
(10) Pub. No.: US 2007/0242444 A1
(43) Pub. Date: Oct. 18, 2007

(54) Conductive Device for Electronic Equipment

(76) Inventor: Sung Suk Ju, Anyang- City (KR)

Correspondence Address: BIRCH STEWART KOLASCH & BIRCH, PO BOX 747, FALLS CHURCH, VA, 22040-0747, US

(21) Appl. No.: 11/628,794

(22) PCT Filed: Mar. 15, 2005
(86) PCT No.: PCT/KR05/00742

§ 371 Date: Mar. 23, 2007

(51) Int. Cl. H05K 9/00

(52) U.S. Cl. 361/818

(57) ABSTRACT

A conductive device for electronic equipment in which conductive media and buffering members are alternately arranged in any direction such that conduction state is maintained in any direction to fully implement electrical shield and since the conduction state is not interrupted even when the conductive device is cut in any direction, and resulting in enhancing reliability of products. The conductive device for electronic equipment includes conductive media and buffering members. The conductive media and the buffering members are alternately arranged in the form of a bar, and plural bars are bonded to each other via the conductive media, forming a conductive plate device. The conductive plate devices are boned to each other by the conductive media and are laminated in multiple layers. The conductive media and the buffering members are aligned with the conductive media and the buffering members in other adjacent bars.

### TECHNICAL FIELD

The present invention relates to a conductive device for electronic equipment, and more particularly, to a conductive device for electronic equipment in which conductive media and buffering members are alternately arranged in the front and rear direction, the right and left direction, and the upward and downward direction such that conduction state is maintained in any direction to fully implement electrical shielding and the conduction state is maintained even when the conductive device is cut in any direction, resulting in enhancing reliability of products.

### BACKGROUND ART

As is well known, various electronic equipments appeared during the industrial development include complex circuits such that high end performance can be implemented in response to consumer demands for various functions, rapid responsiveness, and portability. In particular, portable electronic equipment such as mobile communication terminals is continuously being decreased in size.

However, since several circuits must be integrated in a small space of the high end and small-sized electronic equipment, due to noise, that is, influence of electromagnetic waves, mechanical malfunctions may frequently occur and product quality may also be deteriorated. Moreover, it is well known that the electromagnetic waves emitted from electronic equipment have negative health effects.

Therefore, the electromagnetic waves and static electricity, detrimental to health, are shielded by providing conductivity to gaskets that are disposed to shield electromagnetic waves and static electricity leaked through seams and door crevices for opening and closing the electronic equipment or by providing conductivity to liquid crystal display cushions for supporting liquid crystal displays of digital equipment.

Basically, since general gaskets or general liquid crystal display cushions must have a predetermined thickness and satisfy buffering performance and formability, porous synthetic resins, rubber, silicon, or the like, such as general sponge, ethylene propylene diene monomer, polyurethane foam, or the like are used. In order to manufacture the conductive device by providing conductivity to the above materials, since the above materials are impregnated, coated, or plated with conductive metal, costs for providing conductivity are high and processing thereof is also complicated, resulting in decreased productivity. Since metal powder may be separated from the material provided with conductivity as described above in some materials when the materials are used in shielding electromagnetic waves and static electricity or conductive layers may be separated from the materials as time goes by, kinds, thickness, and hardness of materials serving as the conductive materials are restricted and it is difficult to form conductive layers.

In the case of impregnating, coating, and plating buffering members with conductive metal as described above, conduction in the vertical direction may be possible in the buffering members provided with conductivity. However, since cross-sections where only the buffering members are present when the buffering members are fabricated in a desired shape after providing conductivity, conduction must be interrupted. Due to the above reasons, the buffering members must be provided with conductivity after fabricating the buffering members in the desired shape and mass production is impossible.

Moreover, thick conductive devices are needed in some places where the conductive devices are applied. Since the conduction in the vertical direction is deteriorated in proportion to the thickness of the conductive devices, the thickness of the conductive devices is restricted. Since any conductive device performs only surface conduction and the conduction in the vertical direction, but cannot perform conduction in the lateral direction, the conventional conductive devices have a restriction of shielding harmful electromagnetic waves and static electricity.

### DISCLOSURE

### Technical Problem

Therefore, the present invention has been made in view of the above problems, and it is an object of the present invention to provide a conductive device for electronic equipment in which conductive materials and buffering members are alternately arranged in the front and rear direction, the right and left direction, and the upward and downward direction such that conduction state is maintained in any direction to fully implement electrical shielding and the conduction state is maintained even when the conductive device is cut in any direction, resulting in enhancing reliability of products.

### TECHNICAL SOLUTION

In accordance with an aspect of the present invention, the above and other objects can be accomplished by the provision of a conductive device for electronic equipment comprising conductive media 1 and buffering members 2, the conductive device including the conductive media and the buffering members alternately arranged in the form of a bar, and a plurality of the bars, in which the conductive media and the buffering members are alternately arranged, bonded to each other by the conductive media to form a conductive plate device.

Preferably, the bars of the conductive media and the buffering members are bonded to each other such that the conductive media and the buffering members are aligned with or offset from the conductive media and the buffering members in other adjacent bars.

A plurality of the conductive plate devices are boned to each other by the conductive media and are laminated in multiple layers.

A conductive media and the buffering members in the conductive plate devices are aligned with or offset from the conductive media and the buffering members in other adjacent conductive plate devices.

The conductive media are attached to the upper and lower surfaces of the laminated conductive plate devices.

The conductive media are selected from the group of buffering materials directly coated with conductive material, conductive media such as conductive media in which highly conductive wires or fiber yarns are inserted into the conductive materials to increase the conductivity of the conductive materials, conductive woven fabric, films coated with conductive materials, and metal thin films.

The buffering members are selected from the group of synthetic resins, woven fabric, non-woven fabric, rubber, and films.

The buffering members are provided with conductivity by selecting one from the group and chemically treating the selected one or by inserting highly conductive wire or fabric yarns into the selected one.

### ADVANTAGEOUS EFFECTS

As described above, according to the conductive device for electronic equipment of the present invention, conductive materials and buffering members are alternately arranged in the front and rear direction, the right and left direction, and the vertical direction such that conduction state is maintained in any direction to completely shield electromagnetic waves and static electricity introduced in any direction. Moreover, since there is no cross-section where only buffering member exists even when the conductive device for electronic equipment is cut in any direction, the conduction state is secured after the fabrication. Since the conductive device according to the present invention exhibits high conduction in the right and left direction, in the front and rear direction, and in the vertical direction in the surface conduction fashion even when a minimal quantity of conductive materials more expensive than general buffering members is used, conductivity and shielding performance thereof are excellent in comparison with the conventional conductive devices of similar price. Since the conduction state is guaranteed without damaging characteristics of the buffering members, products having excellent buffering performance using the conductive device of the present invention can be manufactured in comparison with the conventional conductive device.

### DESCRIPTION OF DRAWINGS

The above and other objects, features and other advantages of the present invention will be more clearly understood from the following detailed description taken in conjunction with the accompanying drawings, in which:

FIG. 1 is a perspective view illustrating a conductive device for electronic equipment according to the preferred embodiment of the present invention;

FIG. 2 is a view illustrating an example of the conductive device for electronic equipment, in which conductive materials and buffering members are offset from each other, according to the preferred embodiment of the present invention;

FIG. 3 is a view illustrating an example of the conductive device for electronic equipment, in which conductive materials and buffering members are laminated, according to the preferred embodiment of the present invention; and

FIG. 4 is a view illustrating an example of the conductive device for electronic equipment, in which conductive materials are attached to the upper and lower sides of conductive materials and buffering members, according to the preferred embodiment of the present invention.

### BEST MODE

Hereinafter, a conductive device for electronic equipment according to the preferred embodiments of the present invention will be described in detail with reference to the accompanying drawings.

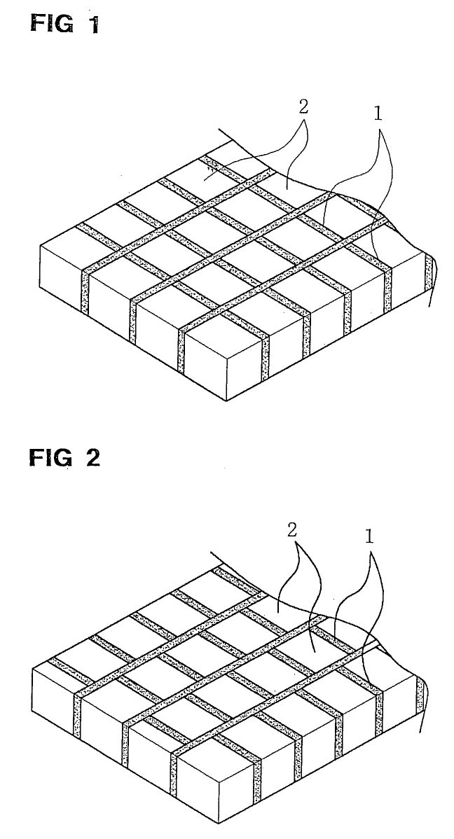

The conductive device for electronic equipment according to the preferred embodiment of the present invention, as shown in FIGS. 1 and 2, is made in the form of a plate, and includes conductive media 1 and buffering members 2 alternately arranged in the form of a bar, and a plurality of bars, in which the conductive media and the buffering members are alternately arranged, bonded to each other by the conductive media. The bars of the conductive media and the buffering members are bonded to each other such that the conductive media and the buffering members are aligned with or offset from the conductive media and the buffering members in other adjacent bars.

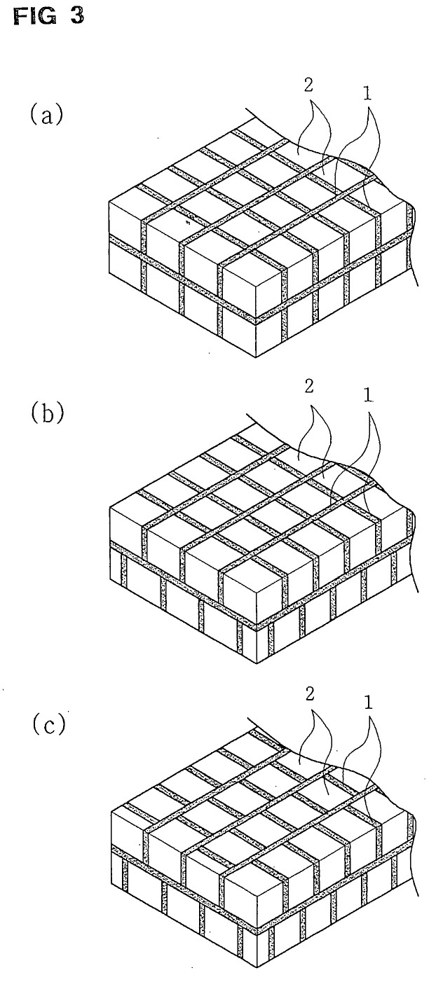

As shown in FIG. 3, a plurality of the conductive plate devices may be bonded to each other by the conductive media 1 and are laminated in multiple layers, while the conductive media 1 and the buffering members 2 in the conductive plate devices are aligned with or offset from the conductive media 1 and the buffering members 2 in other adjacent conductive plate devices.

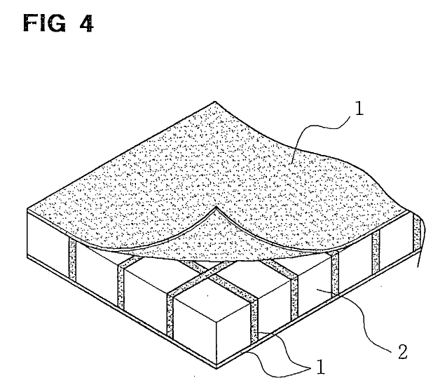

Moreover, as shown in FIG. 4, the conductive media 1 may be attached to the upper and lower surfaces of the laminated conductive plate devices to enhance the surface conductivity of the laminated conductive plate devices.

The conductive media 1 employed in the conductive device according to the preferred embodiment of the present invention are manufactured such that conductive material is directly coated on buffering materials, or are selected from conductive media such as conductive media in which highly conductive wires or fiber yarns are inserted into the conductive materials to increase the conductivity of the conductive materials, conductive woven fabric, films coated with conductive materials, metal thin films such as an aluminum thin film. Any substance such as synthetic resins, woven fabric, non-woven fabric, rubber, films, or the like can serve as the buffering member 2. The buffering members 2 may be provided with conductivity by selecting some substances from the above substances and chemically treating the selected substances or by inserting highly conductive wire or fabric yarns into the selected substances.

Though not depicted in the drawings, when the conductive media 1 and the buffering members 2 are alternately arranged, the conductive media 1 and the buffering members 2 may be bonded to each other by conductive adhesive or general adhesive. However, when the bars in which the conductive media 1 and the buffering members 2 are alternately arranged are bonded to each other by the conductive medium 1 to form the conductive plate device, the conductive adhesive is necessarily used. When laminating the conductive plate devices using the conductive adhesive and attaching the conductive media 1 to the upper and lower sides of the conductive plate device, the conductive adhesive is necessarily used too. When the buffering members 2 can be bonded to each other by the conductive adhesive in the form of a bar without the conductive media 1, a plurality of the bars of the bonded buffering members 2 may be bonded to each other to form a buffering plate member, and the buffering plate members may be laminated in plural layers.

Operation of the conductive device for electronic equipment according to the preferred embodiment of the present invention will be described as follows.

The conductive device for electronic equipment according to the preferred embodiment of the present invention is cut and fabricated in a desired form after manufacturing in the sheet shape. Preferably, when fabricating the conductive device, a conductive device sheet is placed on a cutter and cut in the vertical direction. However, if necessary, the conductive device sheet may be cut in any direction such as in the horizontal direction, in the diagonal direction, or the like.

According to the conventional conductive device, when cutting the conductive device in any direction, there is a serious problem such that there is a possibility that the conventional conductive device may have a cross-section without the conductive media 1 in which only the buffering members 2 are present. If there is a cross-section with only the buffering members 2, the conduction in the cross-section is interrupted so that the conventional conductive device is meaningless as a conductive device.

However, since, in the conductive device according to the preferred embodiment of the present invention, the conductive media 1 and the buffering members 2 are alternately arranged in the front and rear sides and in the right and left sides, conductivity can be maintained in any direction. Therefore, conductivity of the conductive device of the preferred embodiment of the present invention is twice than that of the conventional conductive device, and can shield harmful electromagnetic waves and static electricity introduced in any direction, resulting in enhanced shield capability of products manufactured therefrom. Moreover, since there is no cross-section having only the buffering members 2 even when cutting the conductive device in any direction, the conductivity is guaranteed after cutting and reliability to the conductive device is increased.

In addition, when the bars, in which the conductive media 1 and the buffering members 2 are alternately arranged, are bonded to each other by the conductive media to form the conductive plate device and the conductive plate devices are laminated in several layers, there is no limit in thickness and high conductivity is guaranteed in any direction.

By attaching the conductive media 1 to the upper and lower sides of the conductive device, the surface conductivity of the conductive device is enhanced so that electromagnetic waves and static electricity can be completely shielded.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A conductive device for electronic equipment comprising conductive media 1 and buffering members 2, the conductive device comprising:
the conductive media and the buffering members alternately arranged in the form of a bar; and
a plurality of the bars, in which the conductive media and the buffering members are alternately arranged, bonded to each other by the conductive media to form a conductive plate device.

2. The conductive device for electronic equipment as set forth in claim 1, wherein the bars of the conductive media and the buffering members are bonded to each other such that the conductive media and the buffering members are aligned with the conductive media and the buffering members in other adjacent bars.

3. The conductive device for electronic equipment as set forth in claim 1, wherein the bars of the conductive media and the buffering members are bonded to each other such that the conductive media and the buffering members are offset from the conductive media and the buffering members in other adjacent bars.

4. The conductive device for electronic equipment as set forth in claim 1, wherein a plurality of the conductive plate devices are boned to each other by the conductive media and are laminated in multiple layers.

5. The conductive device for electronic equipment as set forth in claim 4, wherein the conductive media and the buffering members in the conductive plate devices are aligned with the conductive media and the buffering members in other adjacent conductive plate devices.

6. The conductive device for electronic equipment as set forth in claim 1, wherein the conductive media and the buffering members in the conductive plate devices are offset from the conductive media and the buffering members in other adjacent conductive plate devices.

7. The conductive device for electronic equipment as set forth in claim 1, wherein the conductive media are attached to the upper and lower surfaces of the laminated conductive plate devices.

8. The conductive device for electronic equipment as set forth in claim 1, wherein the conductive media are selected from the group of buffering materials directly coated with conductive material, conductive media such as conductive media in which highly conductive wires or fiber yarns are inserted into the conductive materials to increase the conductivity of the conductive materials, conductive woven fabric, films coated with conductive materials, and metal thin films.

9. The conductive device for electronic equipment as set forth in claim 1, wherein the buffering members are selected from the group of synthetic resins, woven fabric, non-woven fabric, rubber, and films.

10. The conductive device for electronic equipment as set forth in claim 9, wherein the buffering members are provided with conductivity by selecting one from the group and chemically treating the selected one or by inserting highly conductive wire or fabric yarns into the selected one.

11. The conductive device for electronic equipment as set forth in claim 4, wherein the conductive media are attached to the upper and lower surfaces of the laminated conductive plate devices.
